(19) United States
(12) Patent Application Publication
(10) Pub. No.: US 2016/0165740 A1
(43) Pub. Date: Jun. 9, 2016

(54) DAMPER AND SERVER USING THE SAME

(71) Applicants: Inventec (Pudong) Technology Corporation, Shanghai (CN); INVENTEC CORPORATION, Taipei (TW)

(72) Inventor: Er-Zhen SONG, Shanghai (CN)

(21) Appl. No.: 14/601,649

(22) Filed: Jan. 21, 2015

(30) Foreign Application Priority Data
Dec. 3, 2014 (CN) 201410723727.2

(51) Int. Cl. H05K 7/14; F16D 63/00

(52) U.S. Cl. CPC H05K 7/1489; F16D 63/008

(57) ABSTRACT

A damper, for a case with a sliding device (e.g., a server), includes an elastic component, a base and a cover. Two sides of the slidable device have two interfering structures, respectively. The dampers are located at two columns of the case which are facing each other, respectively. The base presses against an end of the elastic component. The cover fixes the elastic component by securing the contour of the elastic component. When the slidable device is at first location inside the case, there is a first distance between the damper and the opening of the case and a second distance between the interfering structure and the opening of the case. The second distance is longer than the first distance. When the slidable device slides into/out of the case, the elastic component interferes with the interfering structure.

### CROSS-REFERENCE TO RELATED APPLICATIONS

This non-provisional application claims priority under 35 U.S.C. §119(a) on Patent Application No(s). 201410723727.2 filed in China on Dec. 3, 2014, the entire contents of which are hereby incorporated by reference.

### BACKGROUND OF THE INVENTION

1. Technical Field of the Invention

The disclosure relates to a damper, more particularly to a damper for a server.

2. Description of the Related Art

When used for assisting devices to enter or leave a case, rails effectively reduce the resistance caused by friction between the devices and the case. Furthermore, with the assistance of rails with ball bearings, the resistance caused by the friction between the devices and the case can be substantially reduced. Those heavy devices can be pushed into or pulled out of the case easily thanks to the ballbearing rails.

Though ball bearing rails can assist the heavy devices to be pushed or pulled into or out of the case, but the ball bearing rails also bring some problems. When too much force is applied on the device, inertia from the weight of the device would make the device move in high speed without friction. As a result, the case would be deformed due to the impact by the device moving in high speed, or the device would be damaged due to falling on the ground when the device slides out of the case.

### SUMMARY OF THE INVENTION

The disclosure provides a damper for a server to solve problems about impacts between a sliding device and a case during the sliding device slides into the case and a fall of the sliding device from the case during the sliding device slides out of the case.

An embodiment of the disclosure provides two dampers for a case on which a sliding device is slidably disposed. Two hinders are disposed on two sides of the sliding device which are opposite to each other, respectively. The two dampers are fixed to two columns located at two sides of the case which are opposite to each other, respectively. Each of the dampers comprises an elastic component, a base and a cover. The elastic component has a first end and a second end which are opposite to each other. The base is pressed against the first end of the elastic component. The cover is installed on the base and secures a contour of the elastic component tightly to fix the elastic component. When the sliding device is at a first position inside the case, a first distance is between a front end of the case and each of the dampers, and a second distance is between the front end of the case and each of the hinders. The first distance is shorter than the second distance. When the sliding device is slid into the first position of the case or slid out of the case from the first position, the hinders interfere with the second ends of the elastic components of the dampers, respectively.

According to an embodiment of the disclosure, the second ends of the elastic components protrude from surfaces of the covers, respectively.

According to an embodiment of the disclosure, the elastic components are cylinder-shaped.

According to an embodiment of the disclosure, the elastic components are made of rubber.

According to an embodiment of the disclosure, each of the hinders has a first guiding surface and a second guiding surface. The sliding device is slid out of the first position of the case along a first direction. The sliding device is slid into the case from the first position along a second direction. The first guiding surface corresponds to the first direction. The second guiding surface corresponds to the second direction.

According to an embodiment of the disclosure, the dampers are located between the front end of the case and the hinders, respectively.

According to an embodiment of the disclosure, each of the dampers further has a plurality of fixing holes. A plurality of fixing components penetrate through a plurality of openings of the columns of the case and the plurality of fixing holes to fix the dampers, respectively.

Another embodiment of the disclosure provides a server comprising two dampers and two hinders located at two sides of the server which are opposite to each other, respectively. The server is slidably installed in a case. Each of the dampers comprises an elastic component, a base and a cover. The elastic component has a first end and a second end which are opposite to each other. The base is pressed against the first end of the elastic component. The cover is installed on the base and secures a contour of the elastic component tightly to fix the elastic component. The dampers are fixed at two columns located at two sides of the case which are opposite to each other, respectively. When the server is at a first position inside the case, a first distance is between a front end of the case and each of the dampers, and a second distance is between the front end of the case and each of the hinders. The first distance is shorter than the second distance. When the server is slid into the first position of the case or slid out of the case from the first position, the hinders interfere with the second ends of the elastic components of the dampers, respectively.

According to an embodiment of the disclosure, the dampers are located between the front end of the case and the hinders, respectively.

According to an embodiment of the disclosure, the dampers further has a plurality of fixing holes. A plurality of fixing components penetrate through a plurality of openings of the columns of the case and the plurality of fixing holes to fix the dampers, respectively.

According to the damper and the sever using the same of the disclosure, when the sliding device (e.g., server) is slid into or out of the case, the damper interferes with the interfering structure. The interference between the damper and the interfering structure generates the resistance with the direction opposite to the sliding direction of the sliding device (e.g., server). Hence, the sliding speed of the sliding device (e.g., server) is slowed down. In addition, the interference between the damper and the interfering structure generates a feedback of force to the user so that the user is reminded to control the force applied on the sliding device (e.g., server) and the sliding speed of the sliding device (e.g., server). As a result, the deformations and damages caused by the impacts of the sliding device (e.g., server) and the case or the falling of the sliding device (e.g., server) from the case are avoided.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1A is a schematic view of a case and a sliding device with a damper according to an embodiment of the disclosure;

FIG. 1B is a top view of the case and the sliding device with the damper according to the embodiment of the disclosure;

FIG. 2 is a partial exploded view of the case and the sliding device with the damper according to the embodiment of the disclosure;

FIG. 3 is an exploded view of the damper according to the embodiment of the disclosure;

FIG. 4A and FIG. 4B are top views of the case and the sliding device with the damper when the sliding device is pushed into the case according to the embodiment of the disclosure; and

FIG. 5A and FIG. 5B are top views of the case and the sliding device with the damper when the sliding device is pulled out of the case according to the embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

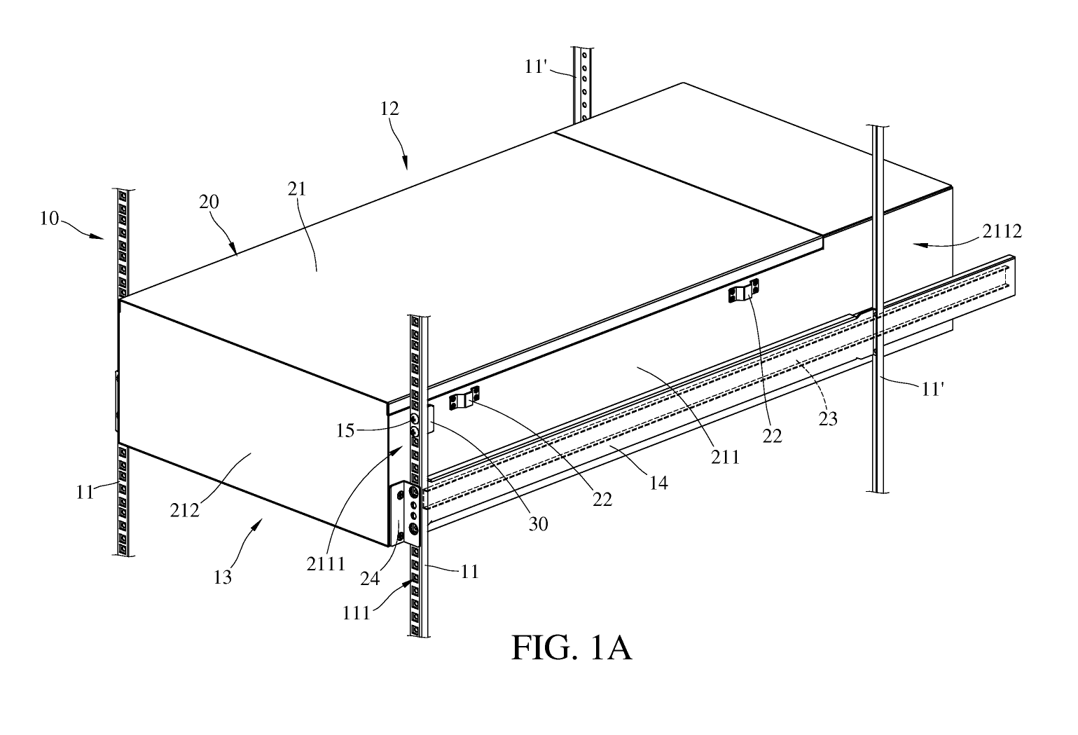

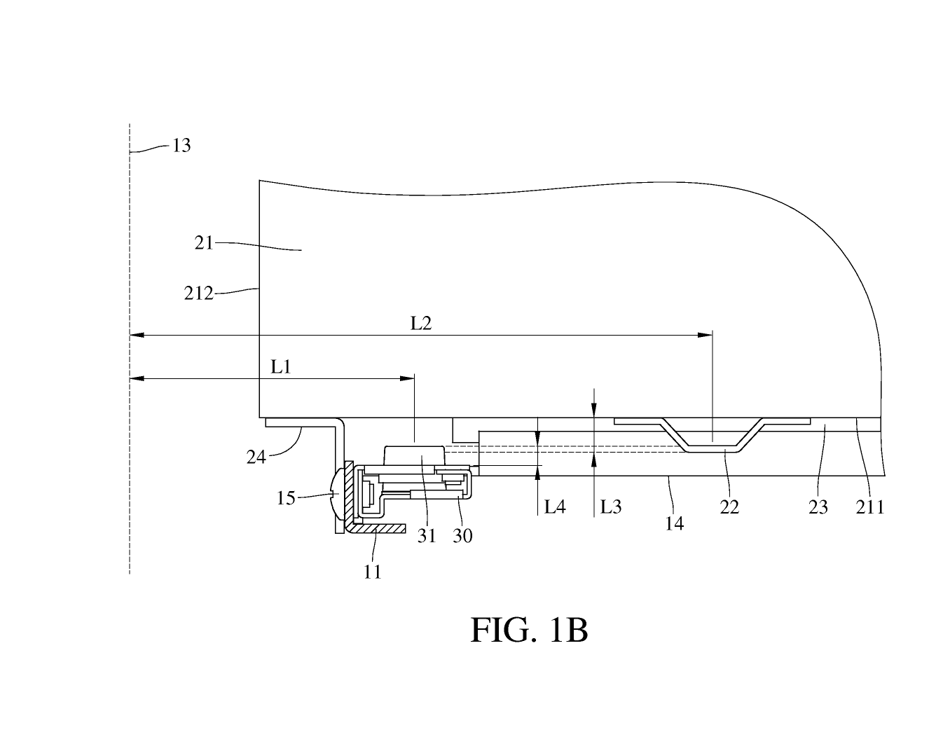

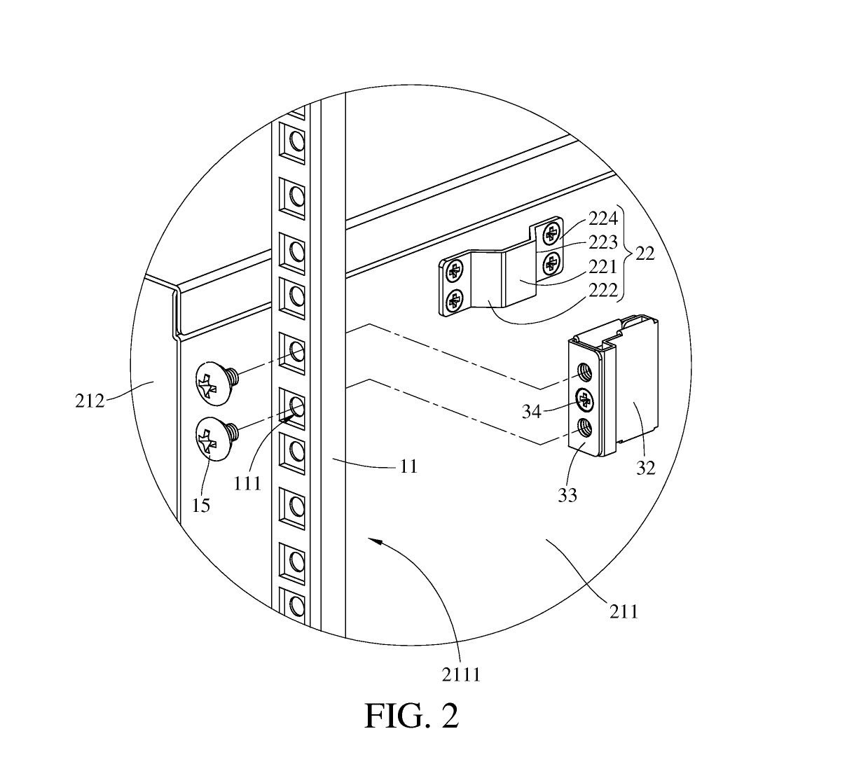

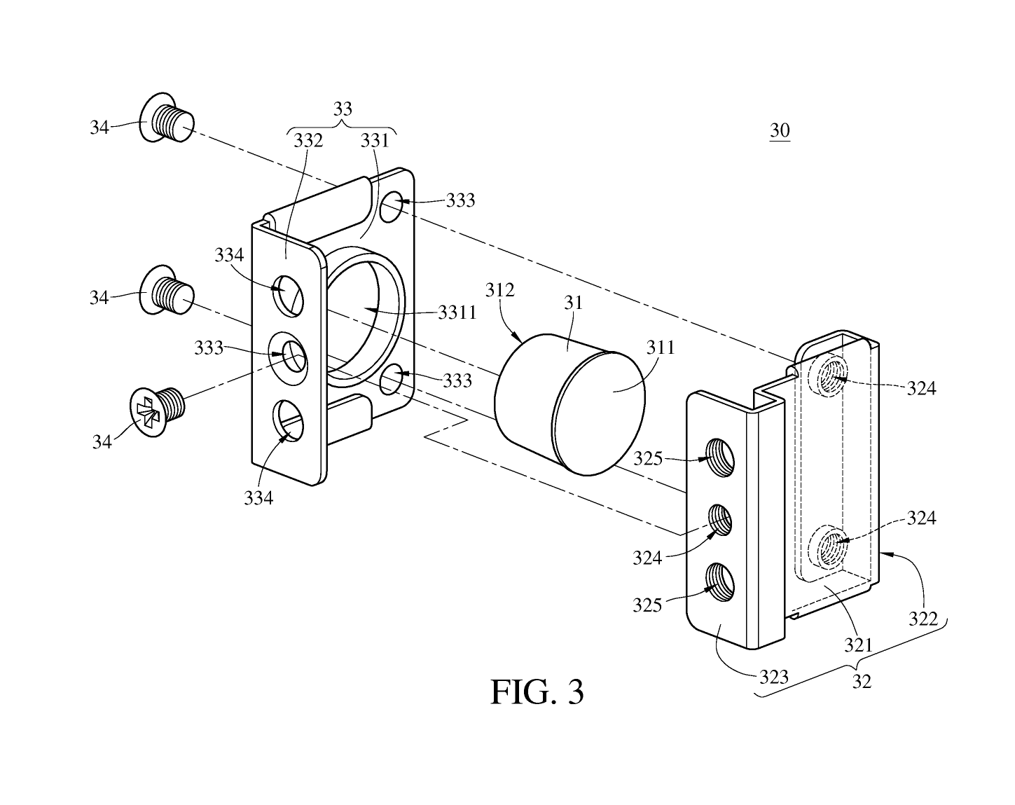

Please refer to FIG. 1 to FIG. 3, FIG. 1A is a schematic view of a case and a sliding device with a damper according to an embodiment of the disclosure. FIG. 1B is a top view of the case and the sliding device with the damper according to the embodiment of the disclosure. FIG. 2 is a partial exploded view of the case and the sliding device with the damper according to the embodiment of the disclosure. FIG. 3 is an exploded view of the damper according to the embodiment of the disclosure.

In the embodiment, two dampers 30 are for a case 10 on which a sliding device 20 is slidably disposed. The case 10 comprises four columns 11, 11′, two sliding rails 14 and a plurality of fixing components 15. The four columns 11, 11′ are paired and arranged at intervals (i.e., by a distance) to form an accommodating space 12. A front end of the case 10 has an opening 13. Objects (i.e., sliding device) can enter and leave the accommodating space 12 through the opening 13. The columns 11, 11′ are located on two sides of the accommodating space 12 which are opposite to each other, respectively. The columns 11, 11′ face to each other, respectively. Two sliding rails 14 are installed on the columns 11, 11′ and facing each other, respectively. The sliding device 20 is pushed to go through the opening 13 and two columns 11 near the opening 13, sequentially, before enter the accommodating space 12. Each of the columns 11, 11′ has a plurality of holes 111, respectively. The plurality of holes 111 and the plurality of fixing components 15 are matched with each other for fixation, respectively.

The sliding device 20 comprises a base body 21, at least two interfering structures 22, two sliding components 23 and two hinders 24. In this and some other embodiment of the disclosure, the sliding device is a server. The sliding device 20 is slid out of the case 10 along a first direction. The sliding device 20 is slid into the case 10 along a second direction.

The base body 21 has two side surfaces 211 and a front surface 212. Two side surfaces 211 are opposite to each other. Each of the side surfaces 211 has a front end 2111 and a rear end 2112 which are opposite to each other. When the base body 21 is located in the accommodating space 12, the front end 2111 is closer to the opening 13 than the rear end 2112. The front surface 212 is located between the front ends 2111 of the side surfaces 211.

In the embodiment, the numbers of the interfering structures 22 are four, and the interference structures 22 are installed on the front ends 2111 and rear ends 2112 of the side surfaces 211 of the base body 21, respectively. However, the disclosure is not limited to the numbers of the interfering structures 22. In other embodiment, the numbers of the interfering structures 22 are two or more than five.

Each of the interference structures 22 has an interfering surface 221, a first guiding surface 222, a second guiding surface 223 and two fixing surface 224. The distance between the interfering surface 221 and the side surface 211 of the base body 21 is the largest distance between the interference structure 22 and the side surface 211 when the interference structure 22 is installed on the side surface 211. The first guiding surface 222 connects one of the fixing surfaces 224 and an end of the interfering surface 221 which is closer to the opening 13 of the case 10 than the other end thereof. An acute angle is formed between a normal direction of the first guiding surface 222 and the first direction along which the sliding device is slid out of the case 10. The second guiding surface 223 connects another one of the fixing surfaces 224 and the other end of the interfering surface 221 which is farther from the opening 13 of the case 10. An acute angle is formed between a normal direction of the second guiding surface 223 and the second direction along which the sliding device is slid into the case 10. The fixing surfaces 224 are fixed on the side surface 211 of the base body 21 so that the interfering structure 22 is fixed to the side surface 211. In the embodiment, the fixing surfaces 224 are fixed on the side surface 211 of the base body 21 by screws. However, the disclosure is not limited to how the fixing surfaces are fixed. In other embodiment, the fixing surfaces are fixed by other methods.

The sliding components 23 are installed on the side surfaces 211 of the base body 21, respectively. The sliding components 23 are matched with the sliding rails 14 on the columns 11, 11′, respectively, so that the sliding device 20 is slidably installed on the columns 11, 11′ of the case 10.

The hinders 24 are installed on the front ends 2111 of the side surfaces 211, respectively. Each of the hinders protrudes out from the side surfaces 211 of the base body 21. When the sliding device 20 is pushed to slide to a first position inside the accommodating space 12, the hinders 24 are stopped by the two columns 11 near the opening 13, respectively, so that the sliding device 20 stops and do not move at the first position in the accommodating space 12.

Each of the dampers comprises an elastic component 31, a base 32, a cover 33 and a plurality of securing components 34. The elastic component 31 has a first end 311 and a second end 312 which are opposite to each other. In the embodiment, the elastic component 31 is cylinder-shaped and made of rubber. However, the disclosure is not limited to the shape and the composition of elastic material of the elastic component.

The base 32 comprises a base part 321, a pressing part 322 and a side part 323. The base part 321 connects the pressing part 322 and the side part 323. The elastic component 31 is installed in a space surrounded by the base part 321, the pressing part 322 and the side part 323. The first end 311 of the elastic component 31 is pressed against the base part 321. The pressing part 322 has at least one first securing hole 324. The side part 323 has at least one first securing hole 324 and at least one first fixing hole 325.

The cover comprises a top covering part 331 and a side connecting part 332 which are connected with each other. The top covering part 331 has a through hole 3311 and at least one second securing hole 334. The side covering part 332 has at least one second securing hole 334 and at least one second fixing hole 334. The width of the through hole 3311 is equal to or slightly smaller than the width of the elastic component 31.

The cover 33 use the sidewalls of the through hole 3311 to secure (e.g., by clamp) the contour of the elastic component 31 and avoid movement of the elastic component 31 relative to the base 32. Hence, the elastic component 31 penetrates the through hole 3311 and is fixed by the holding of the through hole 3311. The second end 312 of the elastic component 31 penetrates the through hole 3311 and protrudes out of a surface of the cover 33. The pressing part 322 of the base 32 presses against the top covering part 331 of the cover 33 so that the first securing hole 324 of the pressing part 32 and the second securing hole 333 of the top covering part 331 are aligned with each other. The side part 323 of the base 32 and the side covering part 332 of the cover 33 are overlapped with each other. Hence, the first securing hole 324 of the side part 323 and the second securing hole 333 of the side covering part 332 are aligned with each other, and the first fixing hole 325 of the side part 323 and the second fixing hole 334 of the side covering part 332 are aligned with each other. The plurality of securing components 34 penetrates the first securing holes 324 and the second securing holes 333, respectively, to secure the elastic component 31, the base 32 and the cover 33 together.

In the embodiment, the number of pair of the first securing hole 324 and the second securing hole 333 which are aligned with each other on the side part 323 and the side covering part 332 is one. However, the disclosure is not limited to the number of pair of the first securing hole and the second securing hole which are aligned with each other on the side part and the side covering part. In other embodiment, the number of pair of the first securing hole and the second securing hole which are aligned with each other on the side part and the side covering part is more than one.

In the embodiment, the number of pair of the first securing hole 324 and the second securing hole 333 which are aligned with each other on the pressing part 322 and the top covering part 331 is two. However, the disclosure is not limited to the number of pair of the first securing hole and the second securing hole which are aligned with each other on the pressing part and the top covering part. In other embodiment, the number of pair of the first securing hole and the second securing hole which are aligned with each other on the pressing part and the top covering part is one or more than two.

In the embodiment, the number of pair of the first fixing hole 325 and the second fixing hole 334 which are aligned with each other is two. However, the disclosure is not limited to the number of pair of the first fixing hole and the second fixing hole which are aligned with each other. In other embodiment, the number of pair of the first fixing hole and the second fixing hole which are aligned with each other is one or more than two.

The dampers 30 are installed on the columns 11 near the opening 13, respectively. The second ends 312 of the elastic components 31 of the dampers 30 face each other. When the sliding device 20 is pushed to slide to the first position inside the accommodating space 12, a first distance L1 is between the opening 13 of the case 10 and each of the dampers 30, and a second distance L2 is between the opening 13 of the case 10 and each of the interfering structures 22 near the opening 13. The first distance L1 is shorter than the second distance L2. Each of the dampers 30 has the plurality of first fixing holes 325 and second fixing holes 334 which are aligned with the plurality of holes 111 on the columns 11, respectively. The plurality of fixing components 15 penetrates the plurality of first fixing holes 325, second fixing holes 334 and holes 111 which are aligned with each other, respectively. Hence, the dampers 30 are fixed on the columns 11 near the opening 13 by the fixing components 15, respectively. It is noted that the locations of the dampers 30 on the columns 11 located within the paths where the interfering structures 22 are moved in or out of the case 10. Furthermore, a third distance L3 is defined as a length of the interfering structure 22 protruding from the side surface 211 of the base body 21. A fourth distance L4 is defined as a length of the elastic component 31 protruding from a surface of the column 11 which is the nearest surface to the sliding device 20. The summation of the third distance L3 and the fourth distance L4 is larger than a distance between the side surface 211 of the base body 21 and the nearest surface to the sliding device 20 of the column 11. As a result, when the sliding device is slid in or out of the case 10, the dampers 30 interfere with the interfering structures 22, respectively.

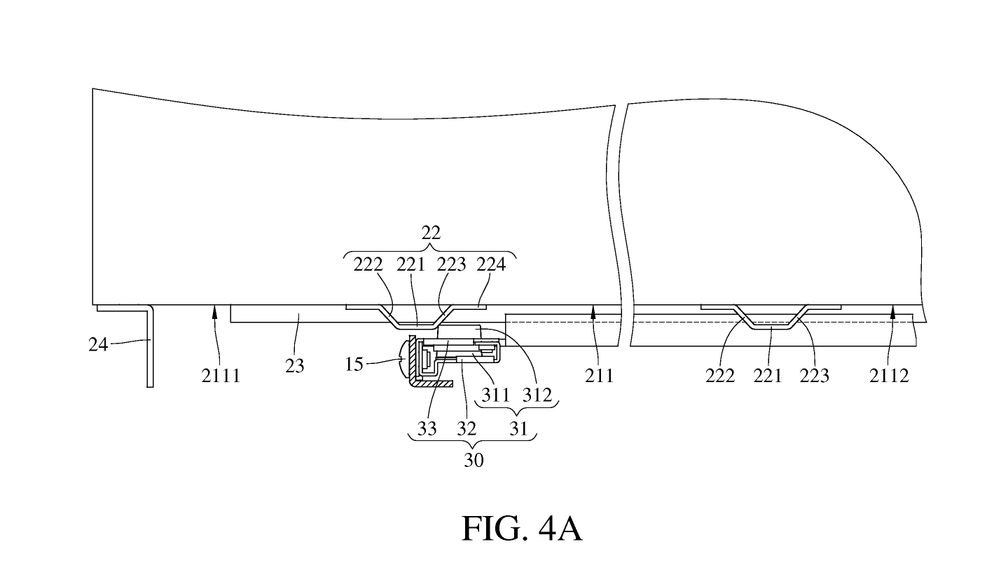

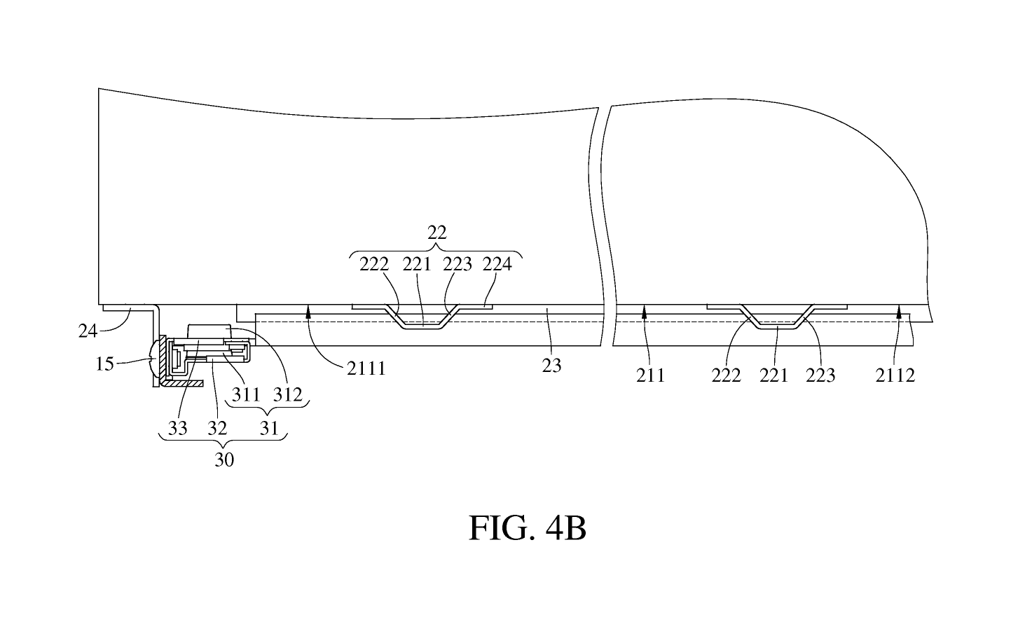

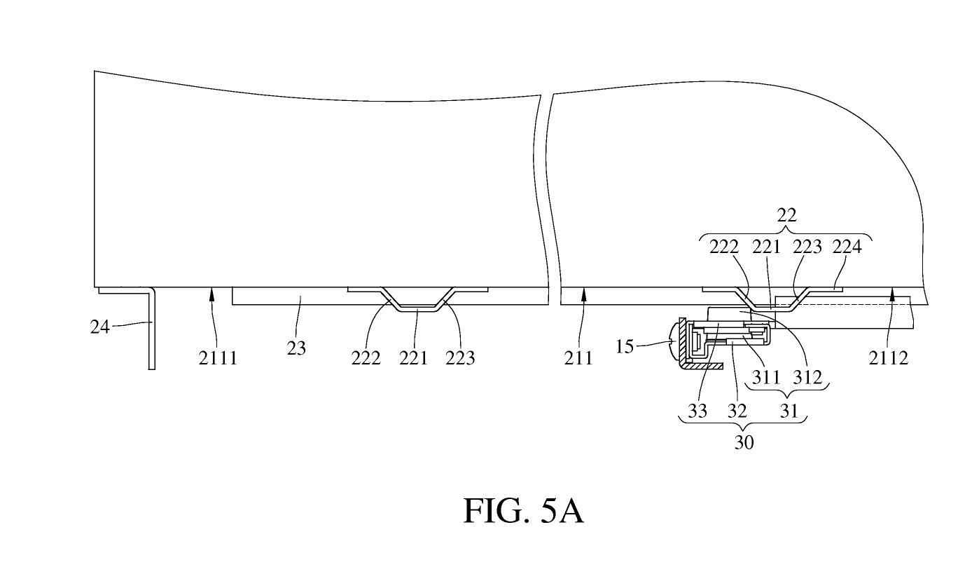

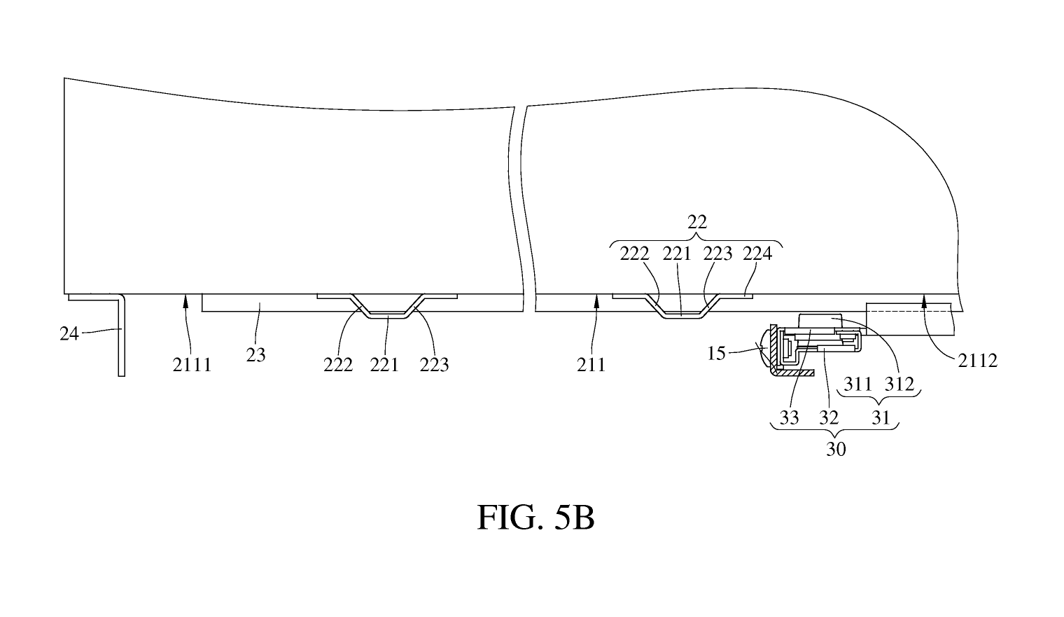

The following describes the operations of the case 10 and the sliding device 20 when the sliding device is pushed to slide into or pulled to slide out of the accommodating space 12 of the case 10. Please referring to FIG. 1 and FIG. 4A to FIG. 5B, FIG. 4A and FIG. 4B are top views of the case and the sliding device with the damper when the sliding device is pushed into the case according to the embodiment of the disclosure. FIG. 5A and FIG. 5B are top views of the case and the sliding device with the damper when the sliding device is pulled out of the case according to the embodiment of the disclosure.

Please referring to FIG. 1, FIG. 4A and FIG. 4B, when the sliding device 20 is pushed to move into the case 10, each of the second ends 312 of the elastic components 31 of the dampers 30 contacts each of the second guiding surfaces 223 of the interfering structures 22, respectively. When the sliding device 20 continues to move into the case 10, the second guiding surfaces 223 guide the second ends 312 of the elastic components 31 to move toward the interfering surfaces 221 of the interfering structures 22, respectively. Hence, the second ends of the elastic components 31 interfere with the interfering surfaces 221 of the interfering structures 22, respectively. Therefore, resistances with a direction opposite to the moving direction of the sliding device 20 are generated. As a result, the resistances slow down the sliding speed of the sliding device 20, and a user can receive feedbacks from the resistances.

When each of the interfering surfaces 221 of the interfering structures 22 located at the front ends 2111 of the side surfaces 211 interferes with the second ends 312 of the elastic components 31, the feedbacks from the resistances remind the user that a majority of volume of the sliding device 20 has been moved into the case 10. Therefore, the user is reminded to reduce his/her force of pushing the sliding device 20 and slow down the sliding speed of the sliding device 20. Hence, the impacts between each of the hinders 24 installed on the front ends 2111 of the side surfaces 211 of the sliding device 20 and each of the columns 11 near the opening 13 are avoided. The deformations and damages caused by the impacts of the hinders 24 and the columns 11 are avoided, too.

Please referring to FIG. 1 FIG. 5A and FIG. 5B, when the sliding device 20 is pulled to move out of the case 10, each of the second ends 312 of the elastic components 31 of the dampers 30 contacts each of the first guiding surfaces 223 of the interfering structures 22, respectively. When the sliding device 20 continues to move out of the case 10, the first guiding surfaces 223 guides the second ends 312 of the elastic components 31 to move toward the interfering surfaces 221 of the interfering structures 22, respectively. Hence, the second ends of the elastic components 31 interfere with the interfering surfaces 221 of the interfering structures 22, respectively, so that resistances with a direction opposite to the moving direction of the sliding device 20 are generated. As a result, the resistances slow down the sliding speed of the sliding device 20, and user gets feed backs from the resistances.

When each of the interfering surfaces 221 of the interfering structures 22 located at the rear ends 2112 of the side surfaces 211 interferes with the second ends 312 of the elastic components 31, the feedbacks from the resistances remind the user that a majority of volume of the sliding device 20 has been moved out of the case 10. Therefore, the user is reminded to reduce the force of pulling the sliding device 20 and slow down the sliding speed of the sliding device 20. Hence, the impacts between the sliding components 23 installed on the side surfaces 211 of the sliding device 20 and the sliding rails 14 of the case 10, respectively, are avoided. The deformations and damages caused by the impacts of the sliding components 23 and the sliding rails 14 are avoided, too. Moreover, the damages of the sliding device 20 caused by falling out from the case 10 are also avoided.

According to the damper and the sever using the same of the embodiments of the disclosure, when the sliding device (e.g., server) is slid into or out of the case, the damper interferes with the interfering structure. The interference between the damper and the interfering structure generates the resistance with the direction opposite to the sliding direction of the sliding device (e.g., server). Hence, the sliding speed of the sliding device (e.g., server) is slowed down. In addition, the interference between the damper and the interfering structure generates a feedback of force to the user so that the user is reminded to control the force applied on the sliding device (e.g., server) and the sliding speed of the sliding device (e.g., server). As a result, the deformations and damages caused by the impacts of the sliding device (e.g., server) and the case or the falling of the sliding device (e.g., server) from the case are avoided.

What is claimed is:

1. A damper is for a case on which a sliding device is slidably disposed, two hinders are disposed on two sides of the sliding device which are opposite to each other, respectively, the two dampers are fixed to two columns located at two sides of the case which are opposite to each other, respectively, each of the damper comprising:
an elastic component having a first end and a second end which are opposite to each other;
a base pressed against the first end of the elastic component; and
a cover installed on the base, the cover securing a contour of the elastic component tightly to fix the elastic component to avoid movement of the elastic component relative to the base;
wherein, when the sliding device is at a first position inside the case, a first distance is between a front end of the case and each of the dampers, a second distance is between the front end of the case and each of the hinders, the first distance is shorter than the second distance, when the sliding device is slid into the first position of the case or slid out of the case from the first position, the hinders interfere with the second ends of the elastic components of the dampers, respectively.

2. The damper of claim 1, wherein the second ends of the elastic components protrude from surfaces of the covers, respectively.

3. The damper of claim 1, wherein the elastic components are cylinder-shaped.

4. The damper of claim 1, wherein the elastic components are made of rubber.

5. The damper of claim 1, wherein each of the hinders has a first guiding surface and a second guiding surface, the sliding device is slid out of the first position of the case along a first direction, the sliding device is slid into the case from the first position along a second direction, the first guiding surface corresponds to the first direction, and the second guiding surface corresponds to the second direction.

6. The damper of claim 1, wherein the dampers are located between the front end of the case and the hinders, respectively.

7. The damper of claim 1, wherein each of the dampers further has a plurality of fixing holes, a plurality of fixing components penetrate through a plurality of openings of the columns of the case and the plurality of fixing holes to fix the dampers, respectively.

8. A server comprising two dampers and two hinders located at two sides of the server which are opposite to each other, respectively, the server is slidably installed in a case, each of the dampers comprising:
an elastic component having a first end and a second end which are opposite to each other;
a base pressed against the first end of the elastic component; and
a cover installed on the base, the cover securing a contour of the elastic component tightly to fix the elastic component;
wherein, the dampers are fixed at two columns located at two sides of the case which are opposite to each other, respectively, when the server is at a first position inside the case, a first distance is between a front end of the case and each of the dampers, a second distance is between the front end of the case and each of the hinders, the first distance is shorter than the second distance, when the server is slid into the first position of the case or slid out of the case from the first position, the hinders interfere with the second ends of the elastic components of the dampers, respectively.

9. The server with damper of claim 8, wherein the dampers are located between the front end of the case and the hinders, respectively.

10. The server with damper of claim 8, wherein the dampers further has a plurality of fixing holes, a plurality of fixing components penetrate through a plurality of openings of the columns of the case and the plurality of fixing holes to fix the dampers, respectively.
